(19) United States
(12) Patent Application Publication
(10) Pub. No.: US 2009/0253259 A1
(43) Pub. Date: Oct. 8, 2009

(54) Solder ball attachment jig and method for manufacturing semiconductor device using the same

(75) Inventors: Jingli Yuan, Suwon-si (KR); Young-Do Kweon, Seoul (KR); Jae-Kwang Lee, Seongnam-si (KR); Jong-Hwan Baek, Seoul (KR); Hyung-Jin Jeon, Gunpo-si (KR); Seung-Wook Park, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD, Suwon (KR)

(21) Appl. No.: 12/222,967

(22) Filed: Aug. 20, 2008

(30) Foreign Application Priority Data
Apr. 2, 2008 (KR) 10-2008-0030822

(51) Int. Cl. H01L 21/60; B23K 37/04

(52) U.S. Cl. 438/613; 228/49.1; 257/E21.509

(57) ABSTRACT

Disclosed are a solder attachment jig and a method of manufacturing a semiconductor device using the same. The solder ball attachment jig, which arranges a solder ball to be aligned with a conductive post of a semiconductor wafer, can include a body and a receiving hole, which is formed on the body to hold the solder ball. Internal walls of the receiving hole that face each other are symmetrically inclined. Using the solder ball attachment jig in accordance with an embodiment of the present invention, the alignment of the solder ball can be improved while reducing the cost and simplifying the processes.

### CROSS-REFERENCE TO RELATED APPLICATIONS

This application claims the benefit of Korean Patent Application No. 10-2008-0030822, filed with the Korean Intellectual Property Office on Apr. 2, 2008, the disclosure of which is incorporated herein by reference in its entirety.

### BACKGROUND

1. Technical Field

The present invention relates to a solder attachment jig and a method of manufacturing a semiconductor device using the same.

2. Description of the Related Art

With today's growing demand for smaller electronic apparatuses, the semiconductor devices used in these electronic apparatuses are becoming smaller and more integrated. In an effort to reduce the size of the semiconductor device, a wafer level chip scale package (WLCSP), which makes the shape of the semiconductor device as closely as the shape of the semiconductor element, has been developed and manufactured.

FIG. 1 is a sectional view showing a semiconductor device in accordance with the related art. As shown FIG. 1, the semiconductor device includes a semiconductor wafer 10 having an electrode pad 12 formed on an upper surface thereof, an insulation layer 14 formed on the upper surface of the semiconductor wafer 10 and exposing the electrode pad 12, a redistribution layer 16 formed on an upper surface of the insulation layer 14 and having one end part connected to the electrode pad 12, a resin layer 18 formed on upper surfaces of the insulation layer 14 and the redistribution layer 16 and exposing the other end part of the redistribution layer 16, an attaching support layer 20 formed on an upper surface of the resin layer 18 and connected to the other end part of the redistribution layer 16, and a solder ball 22 formed on the attaching support layer 20.

Manufacturing the semiconductor device involves photolithography processes to etch the insulation layer 14 in order to expose the electrode pad 12, etch a metal layer in order to form the redistribution layer 16, etch the resin layer 18 in order to expose the redistribution layer 16 and etch a metal layer in order to form the attaching support layer 20. These processes not only make the manufacturing complicated and long but also increase the manufacturing cost, lowering the productivity.

In addition, the solder ball 22 can be attached in irregular alignment and height, making it difficult to accomplish the desired reliability and fine-pitch of the semiconductor device.

### SUMMARY

The present invention provides a solder attachment jig and a method of manufacturing a semiconductor device using the solder attachment jig that can improve the alignment of the solder ball when the solder ball is attached to a semiconductor wafer.

An aspect of the invention features a solder ball attachment jig, arranging a solder ball to be aligned with a conductive post of a semiconductor wafer, the solder ball attachment jig including a body; and a receiving hole, formed in the body to hold the solder ball. Here, inner walls of the receiving hole that are facing each other are symmetrically inclined.

Here, the body can be a silicon wafer and inner walls can be symmetrically curved

The solder ball attachment jig can further include an adjusting piece, interposed between the semiconductor wafer and the solder ball attachment jig and formed with a through hole according to a position of the receiving hole. At this time, the receiving hole can be formed to hold a part of the solder ball.

Another aspect of the invention features a method of manufacturing a semiconductor device including forming a conductive post on a surface of a semiconductor wafer; providing a solder ball attachment jig formed with a receiving hole having inner walls facing each other that are inclined symmetrically; placing a solder ball in the receiving hole; disposing the semiconductor wafer on the solder ball attachment jig to align the solder ball with the conductive post; attaching the solder ball to the conductive post; and removing the solder ball attachment jig.

Here, the conductive post can contain conductive polymer, and the forming the conductive post can be performed by a stencil printing method.

The attaching can be performed by compressing the semiconductor wafer toward the solder ball.

The method can further include, prior to the forming the conductive post, forming an insulation layer on a surface of the semiconductor wafer to expose an electrode pad; and forming a redistribution layer on the surface of the semiconductor layer to be electrically connected to the electrode pad. Here, the forming the conductive post can be performed by forming the conductive post on the redistribution layer. The method can further include, after the removing the solder ball attachment jig, forming an encapsulation layer on the surface of the semiconductor wafer to expose the solder ball.

### BRIEF DESCRIPTION OF THE DRAWINGS

FIG. 1 is a sectional view showing a semiconductor device in accordance with the related art;

FIG. 2 is a flowchart showing how a semiconductor is manufactured in accordance with a first embodiment of the present invention;

FIG. 3 through FIG. 9 are sectional views showing how a semiconductor is manufactured in accordance with the first embodiment of the present invention;

FIG. 10 and FIG. 11 are sectional views showing how a semiconductor is manufactured in accordance with a second embodiment of the present invention; and

FIG. 12 is a sectional view showing how a semiconductor is manufactured in accordance with a third embodiment of the present invention.

### DETAILED DESCRIPTION

The features and advantages of the invention will become more apparent through the below description with reference to the accompanying drawings.

Hereinafter, some embodiments of a method of manufacturing a semiconductor device in accordance with the present invention will be described in detail with reference to the accompanying drawings. Those components that are the same or are in correspondence are rendered the same reference numeral regardless of the figure number, and redundant explanations will be omitted.

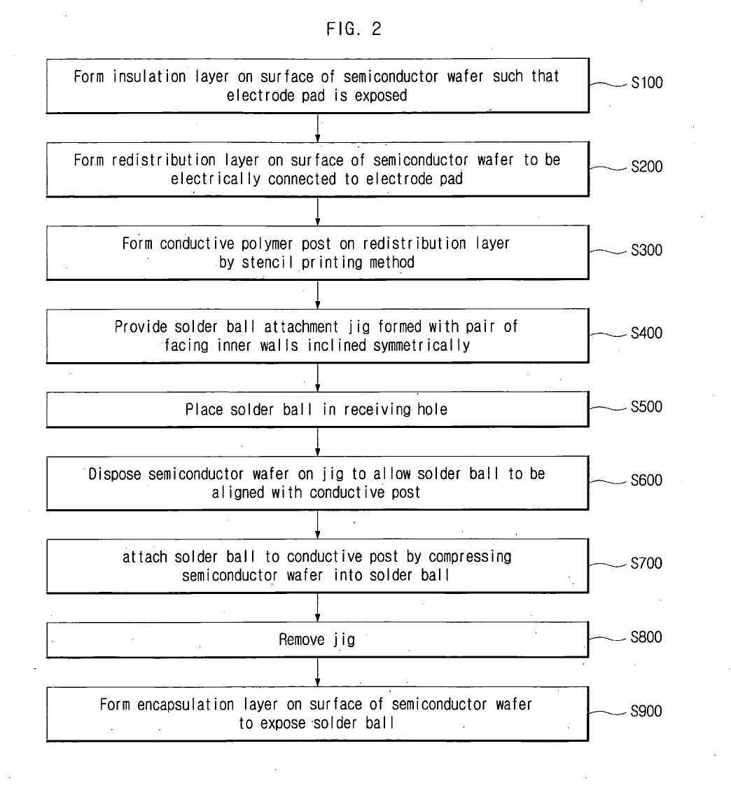

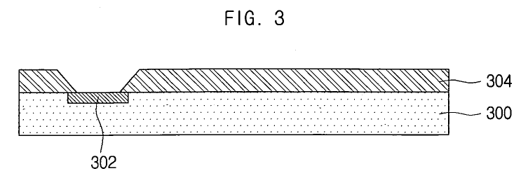

FIG. 2 is a flowchart showing how a semiconductor is manufactured in accordance with a first embodiment of the present invention, and FIG. 3 through FIG. 9 are sectional views showing how a semiconductor is manufactured in accordance with the first embodiment of the present invention. Shown in FIG. 3 through FIG. 9 are a semiconductor wafer 300, an electrode pad 302, an insulation layer 304, a redistribution layer 306, a conductive polymer post 308, an encapsulation layer 310, a solder ball 400, a solder ball attachment jig 600, a body 602, an inner wall 604 and a receiving hole 606.

The method for a semiconductor device in accordance with a first embodiment of the present invention can include forming a conductive post on a surface of the semiconductor wafer 300, providing the solder ball attachment jig 600 in which the receiving hole 606 with a pair of facing inner walls 604 inclined symmetrically is formed, placing the solder ball 400 in the receiving hole 606, disposing the semiconductor wafer 300 on the solder ball attachment jig 600 to allow the solder ball 400 and the conductive post to be aligned with each other, attaching the solder ball 400 to the conductive post and removing the solder ball attachment jig 600. Accordingly, it becomes possible to improve the alignment of the solder ball 400 and the semiconductor wafer 300 with less cost and simpler process. Also, using the conductive polymer post 308 can reduce the stress concentrated on the solder ball. Here, the conductive post can be, for example, the conductive polymer post 308.

As shown in FIG. 3, the insulation layer 304 can be formed on a surface of the semiconductor wafer 300 such that the electrode pad 302 is exposed, in a step represented by S100. The semiconductor wafer 300 can be a processed silicon wafer on which a pattern is formed. The electrode pad 302 can be made of a conductive metal to be electrically connected to the outside of the semiconductor wafer 300.

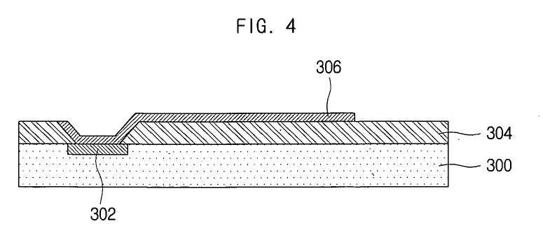

Then, as shown in FIG. 4, the redistribution layer 306 can be formed on a surface of the semiconductor wafer 300 to be electrically connected to the electrode pad 302, in a step represented by S200. The redistribution layer 306 can be formed by allowing a metal layer to be formed on the insulation layer 304 through a vacuum deposition process and then to be etched through a photolithography process.

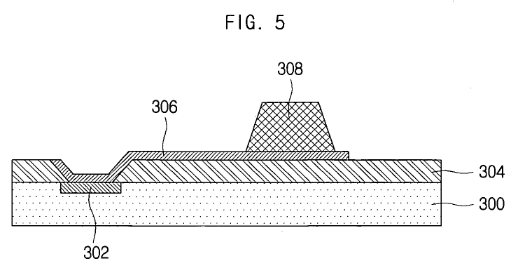

After that, as shown in FIG. 5, the conductive polymer post 308 can be formed by a stencil printing method, in a step represented by S300. Using the conductive polymer post 308 can omit the photolithography process to form an attaching support layer for connecting the solder ball 400 to the redistribution layer 306. This can simplify the manufacturing process and shorten the manufacturing time, thereby cutting down the cost and improving the productivity.

Besides, the conductive polymer post 308 can be enveloped by the below-described encapsulation layer 310, to thereby disperse the stress concentrated on the solder ball 400, preventing the solder ball from cracking and breaking. In effect, this can improve the reliability of the semiconductor device.

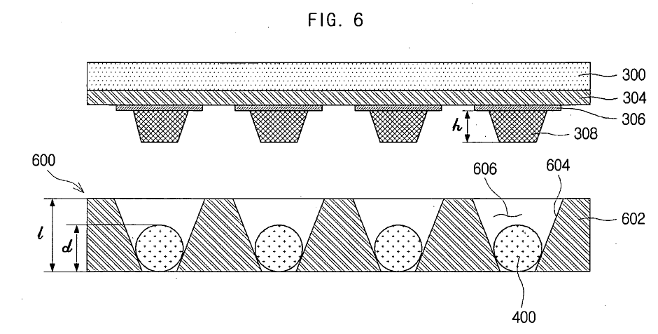

Then, it is possible to provide the solder ball attachment jig 600 formed with a pair of facing inner walls 604 inclined symmetrically, in a step represented by S400. As shown in FIG. 6, the solder ball attachment jig 600, which is a device arranging the solder ball to be aligned with the conductive polymer post 308 of the semiconductor wafer 300, can include a body 602 and the receiving hole 606 formed on the body 602 to hold the solder ball 400. The inner walls 604 of the receiving hole 606 that are facing each other can be inclined in opposite directions. The solder ball attachment jig 600 can be formed with a plurality of receiving holes 606.

The depth 1 by which the solder ball 400 is placed in the accommodating 606 can be smaller than the sum of the lengths h and d of the conductive polymer post 308 and the solder ball 400. Accordingly, compressing the semiconductor wafer 300 into the solder ball 400 can make it possible to attach the solder ball 400 to the conductive post.

At this time, the body 602 can be a silicon wafer. The solder ball attachment jig 600 can be formed by wet-etching or dry-etching the silicon wafer. Of the crystal faces of the silicon wafer, a face having a certain direction can undergo etching with a direction of a much quicker etching speed than other faces. This is referred to as an anisotropic etching.

For example, a (100) face and a (110) face can have different etching speeds. In the case of a small width of a mask, a silicon wafer of a <100> direction can undergo a V-shaped etching with an inclination angle of 54.7 degrees.

Forming the receiving hole 606 in the silicon wafer and using the receiving hole 606 as the solder ball attachment jig 600 can make it possible to easily arrange the solder ball 400 and simplify the forming of the solder ball attachment jig 600 at a lower cost.

Then, the solder ball 400 can be placed in the receiving hole 606, in a step represented by S500. As shown in FIG. 6, a plurality of conductive polymer posts 308 can be formed on the semiconductor wafer 300, and the facing inner walls 604 can arrange the solder ball 400 in an adjusting piece height and also easily align the centers of the inner wall 604 and the conductive polymer post 308.

After that, the semiconductor wafer 300 can be disposed on the solder ball attachment jig 600 to allow the solder ball 400 to be aligned with the conductive post, which is the conductive polymer post 308, in a step represented by S600. The movement of the solder ball 400 held in the receiving hole 606 can be restricted, thereby maintaining the receiving hole 606 in the same height and also aligning the centers of the solder ball 400 and the conductive polymer post 308.

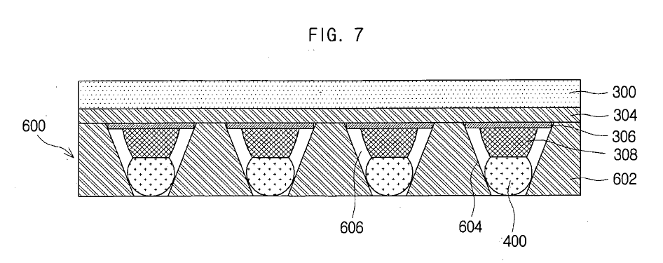

Next, the solder ball 400 can be attached to the conductive polymer post 308 by compressing the semiconductor wafer 300 into the solder ball 400, in a step represented by S700. The conductive polymer post 308 can have the same properties as an electrical conductive adhesive. As a result, the conductive polymer post 308 can be transformed, to thereby be attached to the solder ball 400, as shown in FIG. 7. Using a conductive polymer makes it possible to omit a reflow process for attaching the solder ball 400.

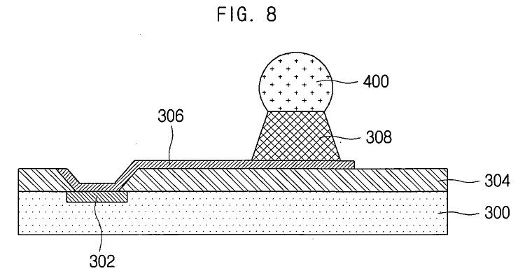

After that, the solder ball attachment jig 600 can be removed in a step represented by S800. As shown in FIG. 8, the solder ball attachment jig 600 can be removed and the solder ball 400 can be attached to the conductive polymer post 308. As a result, the alignment of the solder ball 400 can be improved by using the solder ball attachment jig 600. This can make it possible to enhance the reliability of the semiconductor device 300 and to manufacture a fine-pitch semiconductor device.

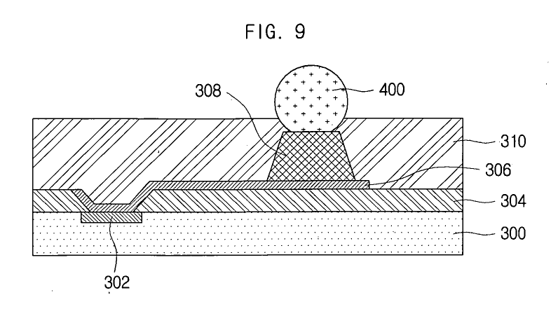

Then, as shown in FIG. 9, the encapsulation layer 310 can be formed on a surface of the semiconductor wafer 300 to expose the solder ball 400, in a step represented by S900. The encapsulation layer 310 can be formed by applying a material, such as epoxy resin, to a surface of the semiconductor wafer 300.

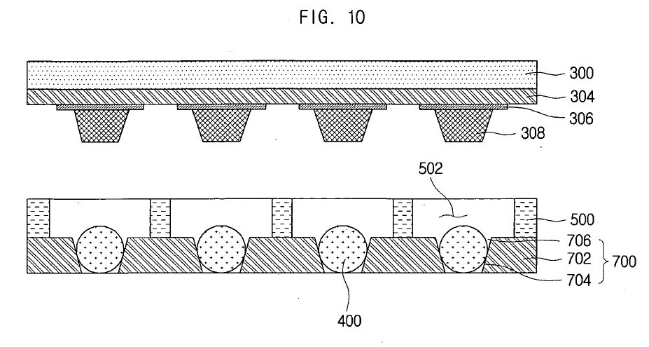

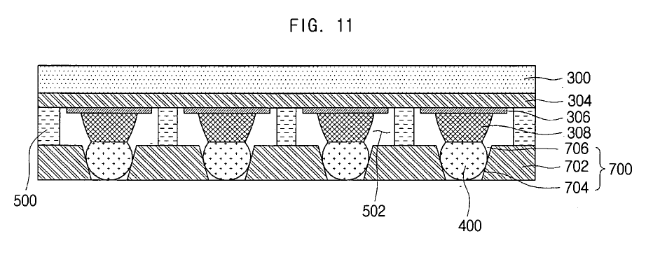

FIG. 10 and FIG. 11 are sectional views showing how a semiconductor is manufactured in accordance with a second embodiment of the present invention. The method of manufacturing a semiconductor device can use a solder ball attachment jig 700 further including a regulator 500, interposed between the semiconductor wafer 300 and the solder ball attachment jig 700 and formed with the through hole 502 according to the position of a receiving hole 706.

The second embodiment can be performed by replacing the solder ball attachment jig 600 with the solder ball attachment jig 700 in the first embodiment of the present invention.

As shown in FIG. 10, the receiving hole 706 can be formed to hold a part of the solder ball 400. The regulator 500 can have an adjustable width. This can mean that the distance between the solder ball 400 and the semiconductor wafer 300 is adjustable. The length of the conductive polymer post 308 can vary in various ways according to design specifications. Accordingly, adjusting the width of the regulator 500 can deal with variable lengths of the conductive polymer post 308.

The regulator 500 can also be a silicon wafer. Like the receiving hole 606, the through hole 502 can also be formed by wet-etching or dry-etching the silicon wafer.

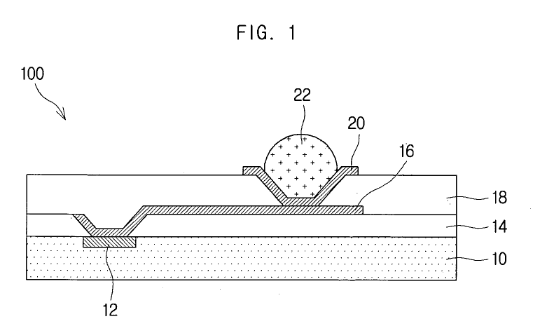

As shown in FIG. 1, the solder ball 400 can be attached to the conductive polymer post 308 by compressing the semiconductor wafer 300 into the solder ball 400.

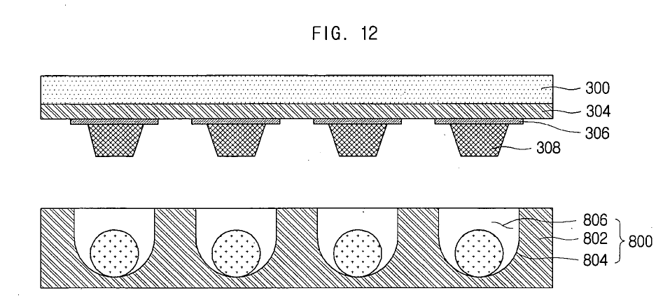

FIG. 12 is a sectional view showing how a semiconductor is manufactured in accordance with a third embodiment of the present invention. In accordance with the third embodiment of the present invention, the solder ball 400 can be arranged by using a solder ball attachment jig 800 including receiving holes 806 having pairs of facing inner walls 804 curved symmetrically.

The third embodiment can be performed by replacing the solder ball attachment jig 600 with the solder ball attachment jig 800 in the first embodiment of the present invention.

The solder ball attachment jig 800 can be formed by wet-etching or dry-etching a silicon wafer. If the solder ball is placed in the receiving hole 806 having the curved inner walls 804, the spherical solder ball 400 can be disposed on a bottom of the receiving hole 806 by the gravity.

This can allow the solder ball 400 to have an adjusting piece height and position, to thereby improve the alignment of the conductive polymer post 308 and the solder ball 400.

Hitherto, although some embodiments of the present invention have been shown and described, it shall be appreciated by any person of ordinary skill in the art that a large number of modifications, permutations and additions are possible within the principles and spirit of the invention, the scope of which shall be defined by the appended claims and their equivalents.

What is claimed is:

1. A solder ball attachment jig, arranging a solder ball to be aligned with a conductive post of a semiconductor wafer, the solder ball attachment jig comprising:
a body; and
a receiving hole, formed in the body to hold the solder ball,
wherein inner walls of the receiving hole that are facing each other are symmetrically inclined.

2. The solder ball attachment jig of claim 1, wherein the body is a silicon wafer.

3. The solder ball attachment jig of claim 1, wherein the inner walls are symmetrically curved.

4. The solder ball attachment jig of claim 1, further comprising an adjusting piece, interposed between the semiconductor wafer and the solder ball attachment jig and formed with a through hole according to a position of the receiving hole.

5. The solder ball attachment jig of claim 4, wherein the receiving hole is formed to hold a part of the solder ball.

6. A method of manufacturing a semiconductor device, the method comprising:
forming a conductive post on a surface of a semiconductor wafer;
providing a solder ball attachment jig formed with a receiving hole having inner walls facing each other that are inclined symmetrically;
placing a solder ball in the receiving hole;
disposing the semiconductor wafer on the solder ball attachment jig to align the solder ball with the conductive post;
attaching the solder ball to the conductive post; and
removing the solder ball attachment jig.

7. The method of claim 6, wherein the conductive post contains conductive polymer.

8. The method of claim 7; wherein the forming the conductive post is performed by a stencil printing method.

9. The method of claim 7, wherein the attaching is performed by compressing the semiconductor wafer toward the solder ball.

10. The method of claim 6, further comprising, prior to the forming the conductive post,
forming an insulation layer on a surface of the semiconductor wafer to expose an electrode pad; and
forming a redistribution layer on the surface of the semiconductor layer to be electrically connected to the electrode pad,
wherein the forming the conductive post is performed by forming the conductive post on the redistribution layer.

11. The method of claim 6, further comprising, after the removing the solder ball attachment jig, forming an encapsulation layer on the surface of the semiconductor wafer to expose the solder ball.
